(19) United States
(12) Patent Application Publication
(10) Pub. No.: US 2004/0094194 A1
(43) Pub. Date: May 20, 2004

(54) Solar panel unit

(76) Inventors: David P. Aldoretta, Duluth, GA (US); James S. Davis, Woodstock, GA (US); Mark D. Spittel, Liburn, GA (US); Don E. Vance, Kennesaw, GA (US); Hilda M. Westergren, Marietta, GA (US); Richard Huff, Conyers, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/295,583

(22) Filed: Nov. 15, 2002

(51) Int. Cl. H01L 31/00

(52) U.S. Cl. 136/251; 136/244; 136/291; 136/293

(57) ABSTRACT

A system and method for mounting a solar panel includes a housing and a cover configured to pivotally connect to the housing. The cover disengages the housing when the cover is at a release angle from the housing.

### FIELD OF INVENTION

The present invention relates generally to mounting assemblies and, more particularly, to solar panel units.

### BACKGROUND

In communication systems, it is often desirable to have repeaters interposed between two endpoints in order to permit communication over greater distances than achievable in the absence of repeaters. The repeaters are typically coupled to power sources, which permit the repeaters to amplify received signals.

In some instances, the power supply of a repeater may be a chargeable cell (or battery) that is coupled to a solar panel. As is known, the solar panel receives light and converts the received light into electricity, which is then used to charge the chargeable cell. The chargeable cell then supplies power to the repeaters, thereby permitting the repeaters to properly amplify and relay signals.

While the units that house the solar panels are fairly robust, sometimes a solar panel becomes inoperable due to accumulation of dirt, severance of electrical connections, physical fracturing of the solar panel, etc. When the solar panel becomes inoperable, it often becomes necessary to replace the solar panel or remedy the problem causing the malfunction of the solar panel. Typically, the remedy includes the replacement of the solar panel or other services that require the disassembly of the solar panel. Unfortunately, many solar panel units are difficult to disassemble and assemble.

In view of this, a heretofore-unaddressed need exists in the industry.

### SUMMARY

The present invention provides systems and methods for mounting a solar panel.

Briefly described, one embodiment of the system comprises a housing, and a cover hingedly connected to the housing, the hinged connection being configured to pivot the cover with respect to the housing for movement between a closed position and a range of open positions. The hinged connection is further configured to permit the cover to engage and disengage the housing when the cover is pivoted at a release position with reference to the housing.

The present invention can also be viewed as providing methods for mounting a solar panel. In this regard, one embodiment of the method comprises the steps of securing a solar panel to a cover, the cover having a bar extending from one side of the cover, the bar being substantially parallel to the one side of the cover. Additionally, the method comprises the step of pivotally securing the cover to a housing, the housing having a C-shaped recess, the C-shaped recess having an opening, the opening configured to receive the bar, the bar being transversely inserted into the opening.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a 3-dimensional perspective view of a solar panel unit having a cover, a housing, and a mount.

FIG. 2A is a perspective view of the cover of FIG. 1.

FIG. 2B is a side view of the cover of FIG. 1.

FIG. 2C is a top view of the cover of FIG. 1.

FIG. 2D is a front view of the cover of FIG. 1.

FIG. 3A is a perspective view of the housing of FIG. 1.

FIG. 3B is a side view of the housing of FIG. 1.

FIG. 3C is a top view of the housing of FIG. 1.

FIG. 3D is a back view of the housing of FIG. 1.

FIG. 4A is a perspective view of the mount of FIG. 1.

FIG. 4B is a side view of the mount of FIG. 1.

FIG. 4C is a top view of the mount of FIG. 1.

FIG. 4D is a back view of the mount of FIG. 1.

FIGS. 5A through 5C are exploded views of the C-shaped recess and the bar of FIGS. 2B and 3B, respectively.

FIG. 6 is a flowchart showing one embodiment of the method.

### DETAILED DESCRIPTION OF THE PREFERRED EMBODIMENTS

Having summarized various aspects of the present invention, reference is now made in detail to the description of the embodiments as illustrated in the drawings. While several embodiments are described in connection with these drawings, there is no intent to limit the invention to the embodiment or embodiments disclosed herein. On the contrary, the intent is to cover all alternatives, modifications, and equivalents included within the spirit and scope of the invention as defined by the appended claims.

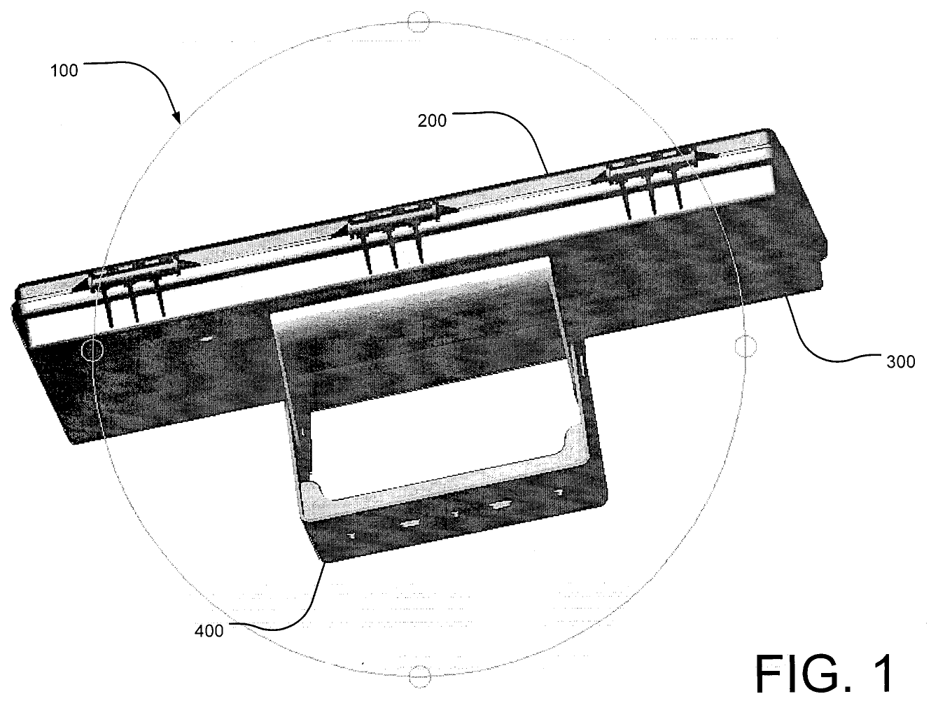

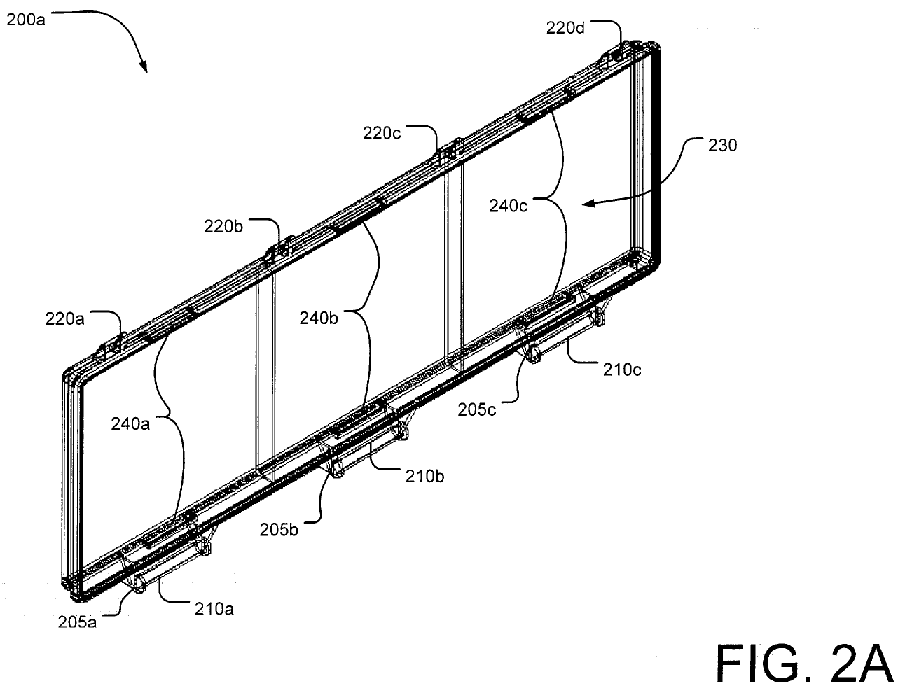

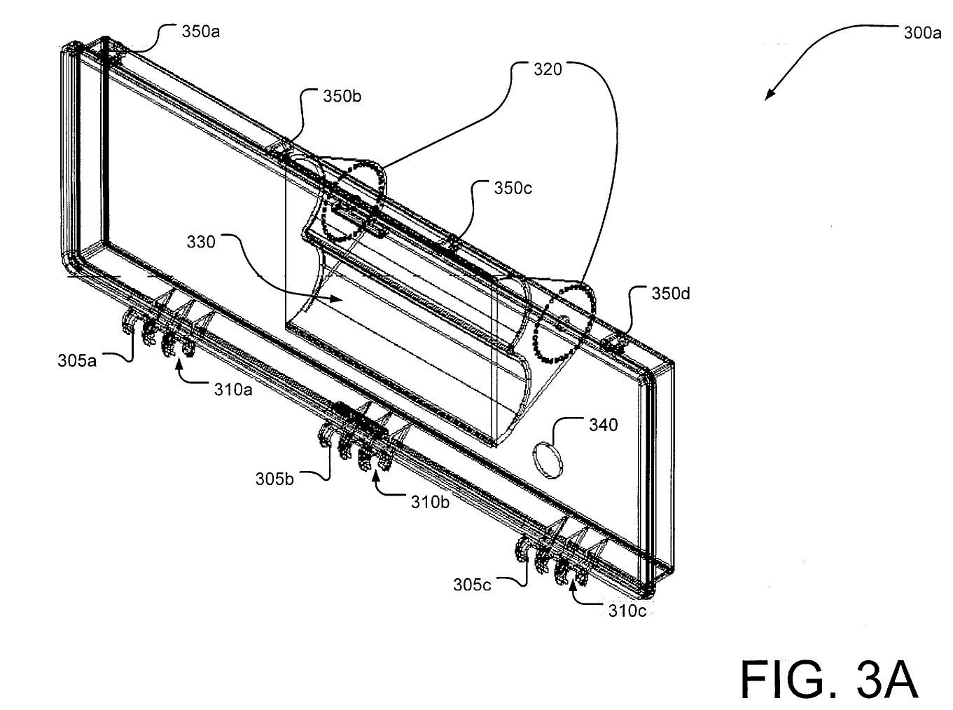

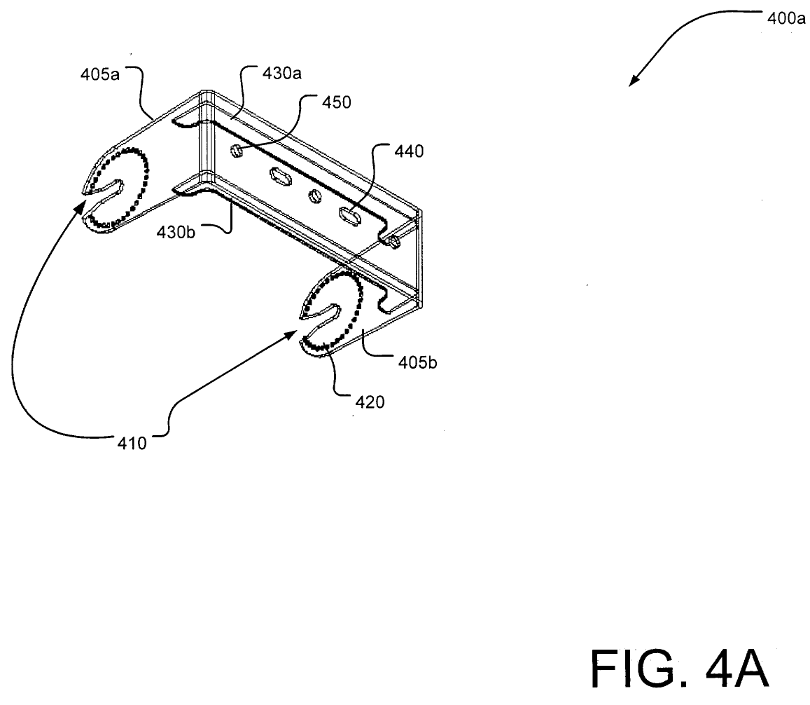

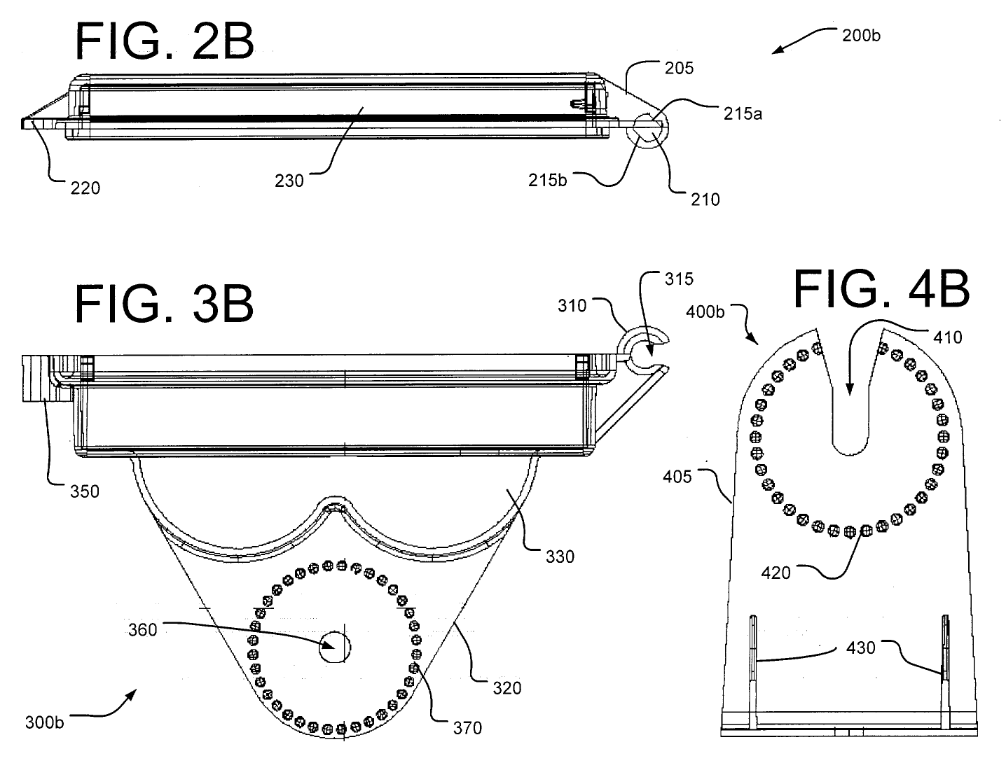

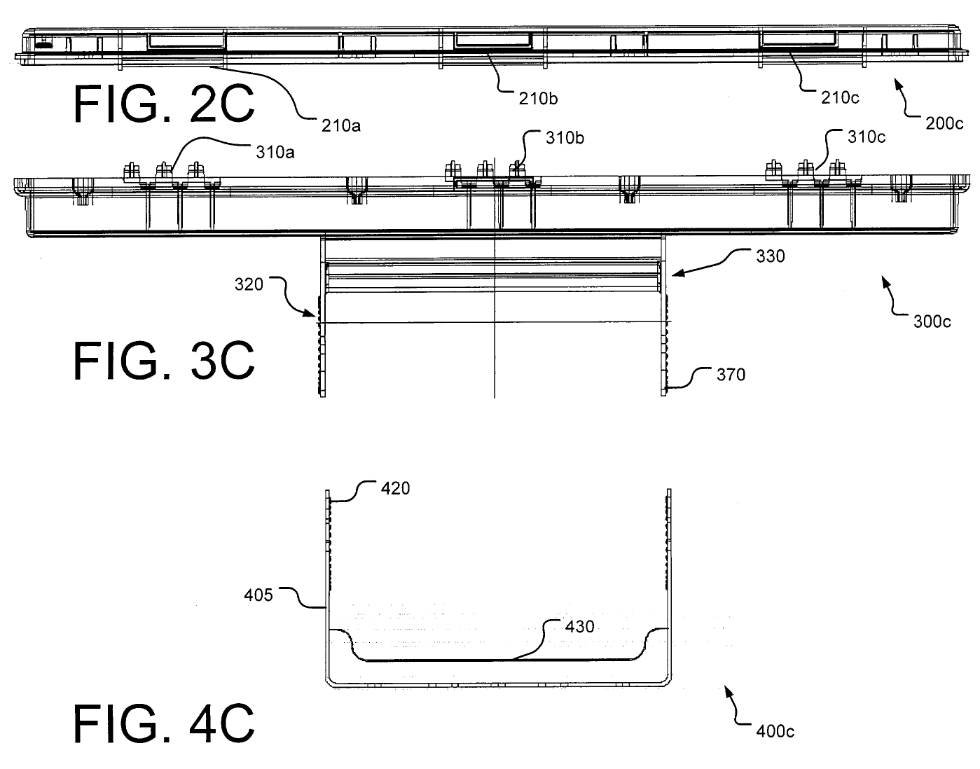

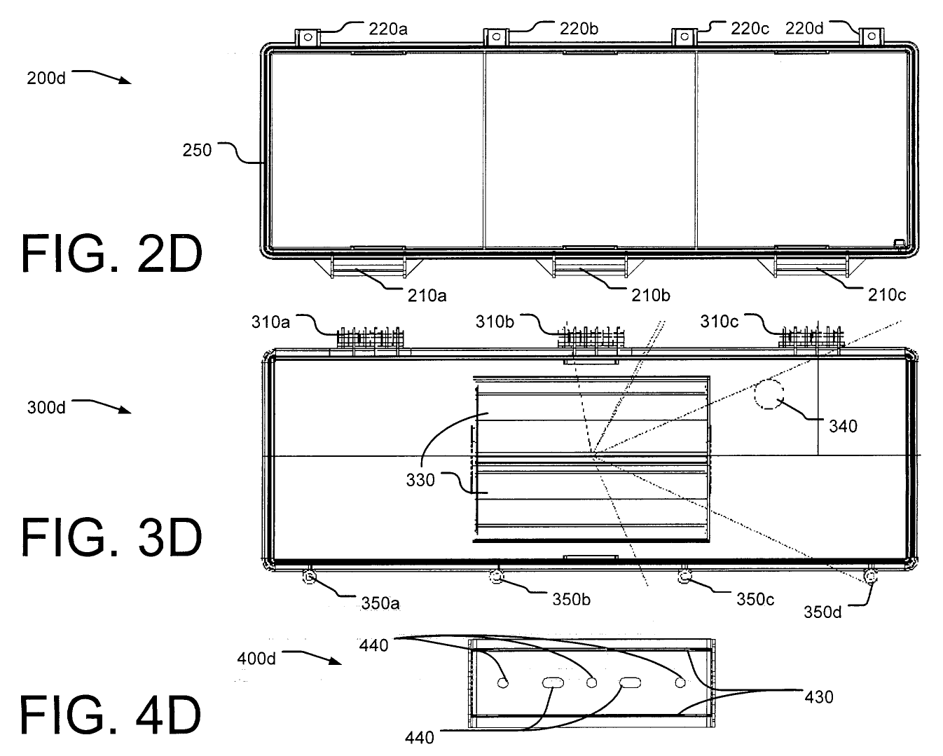

FIG. 1 is a 3-dimensional perspective view of a solar panel unit 100 having a cover 200, a housing 300, and a mount 400. As seen in FIG. 1, the solar panel unit comprises a housing 300 and a cover 200 that engage one another so as to form a flattened box. In one embodiment, the solar panels (not shown here) are placed between the housing 300 and the cover 200 so that the solar panels are encased in the solar panel unit 100 when the housing 300 and the cover 200 engage each other in a closed position. In addition to the housing 300 and the cover 200, the solar panel unit 100 further comprises a mount 400, which permits the mounting of the solar panel to, for example, a non-movable object. The mount 400 is pivotally connected to the housing 300, thereby permitting repositioning of the housing 300 at many different angles with respect to the mount and/or the object to which the mount is attached. The mount 400 is configured to affix to, for example, a pole, a tree, a roof, using a C-clamp, a nail, a screw, adhesive, etc. Further details related to the mount 400, the housing 300, and the cover 200 are discussed with reference to FIGS. 2A through 5C.

FIG. 2A is a perspective view 200a of the cover 200 of FIG. 1. As shown in the embodiment of FIG. 2A, the cover 200 comprises several connectors 205a, 205b, 205c (collectively referred to as connectors 205) that extend from one side of the cover 200. In a preferred embodiment, these connectors 205 have bars 210a, 210b, 210c (collectively referred to as bars 210) that are substantially parallel to the side of the cover 200 from which the connectors 205 extend. These connectors 205 are used to attach the cover 200 to the housing 300, and are discussed in greater detail below.

In addition to the connectors 205, the cover 200 comprises several concavities 230 located inside the cover 200. These concavities 230 are configured to receive solar panels (not shown). Once the solar panels are placed in the concavities 230, the solar panels are secured by brackets (not shown), which are configured to insert into bracket holes 240a, 240b, 240c (collectively referred to as bracket holes 240). The brackets, in a preferred embodiment, may be plastic boards that span the width of the cover 200.

On the side opposing the connectors 205, several cover-locking mechanisms 220a, 220b, 220c, 220d (collectively referred to as cover-locking mechanisms 220) extend from the cover 200. As will be shown below, these cover-locking mechanisms 220 are configured to engage a corresponding set of housing-locking mechanisms (not shown here) on the housing 300. The cover-locking mechanisms 220 are discussed in detail with reference to FIG. 2D.

FIG. 3A is a perspective view 300a of the housing 300 of FIG. 1. As shown in FIG. 3A, the housing 300 comprises several connectors 305a, 305b, 305c (collectively referred to as connectors 305), which extend from one side of the housing 300. In a preferred embodiment, these connectors 305 have C-shaped recesses 310a, 310b, 310c (collectively referred to as C-shaped recesses 310), which are configured to engage the bars 210 of the cover 200. Since the bars 210 are substantially parallel to one side of the cover 200, the bars 210 insert transversely into the C-shaped recesses 310. The engagement of the C-shaped recesses 310 with the bars 210 permits pivotal movement of the cover 200 about the axis of the bars 210. In other words, the engagement of the C-shaped recesses 310 with the bars 210 creates a hinge-type mechanism between the cover 200 and the housing 300, thereby permitting the cover 200 and the housing 300 to pivot around the hinge-type mechanism.

In addition to the connectors 205 having the C-shaped recesses 210, the housing 300 further comprises a mounting protrusion 320 located outside of the housing 300. The mounting protrusion 320 is discussed in greater detail with reference to FIG. 3B. The housing 300 further includes a cavity 330 located inside the housing 300. The cavity 330 is configured to receive a chargeable cell (not shown), which can be charged by the solar panels (not shown). In an alternative embodiment, the cavity 330 is also configured to receive a repeater (not shown). Thus, if it is determined that a desirable location for the solar panel unit 100 coincides with a desirable location for the repeater, then the repeater may be housed within the solar panel unit 100. The cavity 330 is located inside the housing 300, thereby shielding any device in the cavity 330 from elements such as weather or vermin when the cover 200 and the housing 300 are engaged in the closed position.

Since the cavity 330 may house an electronic device (e.g., chargeable cell, repeater, etc.), which would be inside the solar panel unit 100, the housing 300 further includes an orifice 340 that is configured to receive a wire (not shown). The orifice 340 permits electrical coupling between the interior and exterior of the solar panel unit 100.

On the side opposing the connectors 305, several housing-locking mechanisms 350a, 350b, 350c, 350d (collectively referred to as housing-locking mechanisms 350) extend from the housing 300. These housing-locking mechanisms 350 are the corresponding set to the cover-locking mechanisms 220. Thus, when the cover 200 and the housing 300 come together, the cover-locking mechanisms 220 and the housing-locking mechanisms 350 permit the cover 200 to be secured to the housing 300 such that the solar panel unit 100 does not readily open. In a preferred embodiment, the housing-locking mechanisms 350 and the cover-locking mechanisms 220 comprise holes to accommodate screws, locks, bolts, etc., which may be used to secure the cover 200 to the housing 300. In another embodiment, the housing-locking mechanisms 350 and the cover-locking mechanisms 220 comprise extensions that may be joined together by, for example, a clip or a clamp.

FIG. 4A is a perspective view 400a of the mount 400 of FIG. 1. As seen in FIG. 4A, the mount 400 comprises two supports 405a, 405b (collectively referred to as supports 405), which extend from a back 415 in a substantially perpendicular manner. The supports 405 are configured to pivotally engage the mounting protrusions 320 of the housing 300. In this sense, each support 405 has a cutaway 410 that is adapted for a bolt, a screw, or other rotationally invariant securing mechanisms. Thus, once the mounting protrusions 320 of the housing 300 are secured to the supports 405 of the mount 400, the housing 300 may be positioned at various angles with reference to the mount 400. Several features of the supports 405 are shown in greater detail with reference to FIG. 4B.

Since the supports 405 extend substantially perpendicularly from the back 415 of the mount 400, the solar panel unit 100 may experience one-dimensional directional instability in the direction parallel to the back 415 of the mount 400. In order to remedy this, the mount 400 also includes braces 430a, 430b (collectively referred to as braces 430), which are interposed between the supports 405, thereby providing structural support in the unstable direction. In addition to the supports 405 and braces 430, the mount 400 comprises slots 440, 450 that are used to secure the mount 400 to, for example, a tree, a pole, a roof, etc. These slots 440, 450 are discussed in greater detail with reference to FIG. 4D.

FIG. 2B is a side view 200b of the cover 200 of FIG. 1. While FIG. 2B shows the cover-locking mechanism 220 and the concavity 230, since these components have been discussed with reference to FIG. 2A, further discussion of these components is omitted with reference to FIG. 2B.

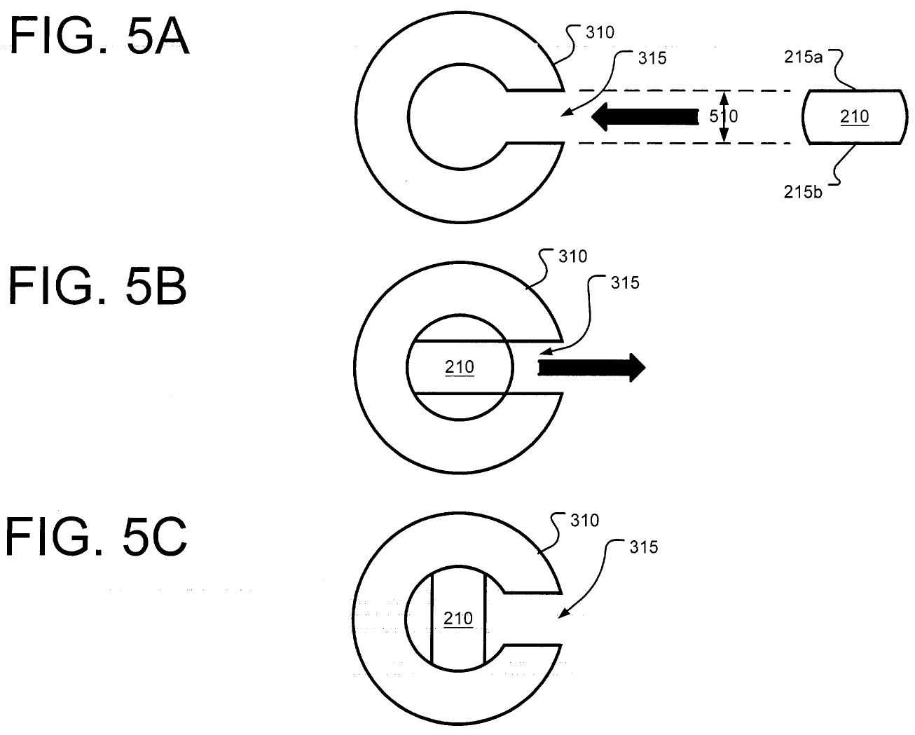

The side view 200b of FIG. 2B shows, in greater detail, the connector 205 that is configured to pivotally engage the cover 200 to the housing 300. As shown in FIG. 2B, the connector 205 has a bar 210 that is positioned substantially parallel to one side of the cover 200. The side view 200b shows an axial view of the bar 210. As seen from the axial view, the bar 210 has a cross-section defined by a generally circular outer circumference having two opposing flattened portions 215a, 215b. As such, the bar 210 has the appearance of a “flattened cylinder,” or a cylinder having two opposing sides removed. As will be shown with reference to FIGS. 5A through 5C, the flattened portions 215a, 215b permit efficient assembly and disassembly of the solar panel unit 100.

FIG. 3B is a side view 300b of the housing 300 of FIG. 1. As shown in FIG. 3B, the profile of the cavity 330 is substantially U-shaped, thereby accommodating items such as, for example, E-cell batteries.

The C-shaped recesses 310 of the connectors 305 are also highlighted in FIG. 3B. As seen in conjunction with FIG. 2B, the C-shaped recess 310 is configured to receive the bar 210, thereby permitting the cover 200 to pivotally engage the housing 300. Since the C-shaped recess 310 has an opening 315 only on one side, the bar 210 may only be transversely inserted through the opening 315. This is shown in greater detail with reference to FIGS. 5A through 5C.

Another feature more clearly shown in FIG. 3B is the mounting protrusion 320. As seen in FIG. 3B, the mounting protrusion 320 comprises a hole 360 that is adapted for a bolt, screw, or other rotationally invariant securing mechanism. This permits the mounting protrusion 320 to pivotally couple with the supports 405 of the mount 400 as described with reference to FIG. 4A. The mounting protrusion 320 further comprises friction points 370, each of which is located at a predefined radius from the center of the hole 360. In this sense, the locus of friction points 370 exhibits a circular pattern around the hole 360. These friction points 370 are configured to inhibit pivoting between the housing 300 and the mount 400. This is discussed further with reference to FIG. 4B.

While the housing securing mechanism 350 is also shown in FIG. 3B, further description of the housing securing mechanism 350 is tabled until the discussion of FIG. 3D.

FIG. 4B is a side view 400b of the mount 400 of FIG. 1. While FIG. 4B shows the support 405 and the braces 430, since these components have been described with reference to FIG. 4A, further discussion of these components is omitted here. Of special concern with reference to FIG. 5B is the cutaway 410 and several mount friction points 420. As described with reference to FIG. 4A, the supports 405 are configured to pivotally engage the mounting protrusions 320 of the housing 300. Thus, the cutaway 410 is adapted for a bolt, screw, or any other rotationally invariant securing mechanism, which secures the cutaway 410 to the hole 360 of the mounting protrusion 320 on the housing 300. In this sense, if a rotationally invariant securing mechanism is used to couple the support 405 of the mount 400 to the mounting protrusion 320 of the housing 300, then the housing 300 may be positioned at a variety of angles with reference to the mount 400.

In addition to the cutaway, the mount 400 comprises mount friction points 420, which exhibit a circular pattern similar to the friction points 370 on the housing 300. Once the supports 405 of the mount 400 are engaged to the mounting protrusion 320 of the housing 300, the circular pattern of the mount friction points 420 overlaps with the circular pattern of the friction points 370 on the housing 300. Thus, when the rotationally invariant securing mechanism is tightened to secure the mount 400 to the housing 300, each of the friction points 370 on the housing 300 engages a corresponding mount friction point 420 on the mount 400. Hence, the housing 300 may be secured at various discrete angles with reference to the mount 400. Once the mount friction points 420 engage the friction points 370 on the housing 300, the rotationally invariant securing mechanism may be loosened to disengage the mount friction points 420 from the friction points 370 on the housing 300. The loosening of the rotationally invariant securing mechanism permits the repositioning of the housing 300 with reference to the mount 400.

FIGS. 2C, 3C, and 4C are top views 200c, 300c, 400c of the cover 200, the housing 300, and the mount 400, respectively. Since all of the components of FIGS. 2C, 3C, and 4C have been discussed above, only a cursory discussion is presented here. The top views 200c, 300c, 400c facilitate the depiction of how the cover 200, the housing 360, and the mount 400 assemble. As shown in these figures, The back side of the cover 200 engages the front side of the housing 300, thereby creating a box-like structure when the cover and the housing 300 are engaged and secured (i.e., closed). The back side of the housing 300 engages the supports 405 of the mount 400, thereby coupling the mount friction points 420 to the friction points 370 on the housing 300. This permits the pivotal movement of the housing 300 with reference to the mount 400.

FIG. 2D is a front view 200d of the cover 200 more clearly illustrating the cover-locking mechanism 220 and the bracket holes 240. As described with reference to FIG. 2A, once the solar panels are placed in the concavities 230 of the cover 200, the solar panels are secured by brackets (not shown), which are configured to insert into the bracket holes 240. As shown in FIG. 2D, the bracket holes 240 are located at counterpoised sides of the cover 200, thereby permitting one side of a bracket to insert into one bracket hole 240 and another side of the bracket to insert into the counterpoised bracket hole 240. This configuration effectively sandwiches the solar panel between the cover 200 and the bracket, thereby securing the solar panel to the cover 200 of the solar panel unit 100.

Several cover-locking mechanisms 220 are also clearly visible in FIG. 2D. As shown in this embodiment, the cover-locking mechanisms 220 extend from the cover 200 at a side opposite the connectors 210. These cover-locking mechanisms 220 are configured to engage a companion set of housing-locking mechanisms 310 on the housing 300. Specifically, each cover-locking mechanism 220 in the embodiment of FIG. 2D has a hole, thereby permitting the insertion of a screw, nail, bolt, wire, or any other securing mechanism into the hole to lock the cover 200 to the housing 300. This is explained in greater detail with reference to FIG. 3D.

FIG. 3D is a back view 300d of the housing 300 of FIG. 1. The cavity 330, the housing-locking mechanism 350, and the orifice 340 are more clearly illustrated in FIG. 3D. As discussed with reference to FIG. 3A, the housing 300 includes a cavity 330 located inside the housing 300. The cavity 330 is configured to receive a chargeable cell (not shown), which can be charged by the solar panels (not shown). In an alternative embodiment, the cavity 330 may also be configured to receive a repeater (not shown) if it is determined that a desirable location for the solar panel unit 100 coincides with a desirable location for the repeater. Since the cavity 330 is inside the housing 300, the housing 300 shields any device in the cavity 330 from elements such as weather or vermin when the cover 200 is securely placed on the housing 300. As shown in the preferred embodiment of FIG. 3D, the cavity 330 is located at the center of the housing, thereby providing a relatively symmetric weight distribution to the solar panel unit 100. Additionally, if the cavity 330 is formed into the housing 300 by, for example, an injection molding process, then that portion that defines the cavity 330 may protrude from the housing 300 as shown in FIG. 3A. Strategic configuring of the cavity 330 results in a protrusion that may be used to provide added structural integrity to the mounting protrusion 320.

As described with reference to FIG. 3A, the cavity 330 includes an orifice 340 that is configured to receive a wire (not shown), which permits electrical coupling between the interior and exterior of the solar panel unit 100. The size of the orifice 340 is determined by the number of wires that span the interior and exterior of the solar panel unit 100, the diameter of the wires, etc. One problem with having such an orifice 340 is that the orifice 340 may expose the interior of the solar panel unit 100 to elements such as water, vermin, etc. In order to prevent such exposure, a stopper (not shown) or a gasket (not shown) may be used to fill any gaps that may remain after the insertion of the wire.

The housing-locking mechanisms 350, as shown in FIG. 3D, correspond to the cover-locking mechanisms 220. Thus, when the cover 200 and the housing 300 engage, the cover-locking mechanism 220 and the housing-locking mechanism 350 permit the cover 200 to be secured to the housing 300, such that the solar panel unit 100 does not readily open. Similar to the cover-locking mechanisms 220 the housing-locking mechanisms 350 comprise holes to accommodate a screw, lock, bolt, etc., which may be used to secure the cover 200 to the housing 300. In another embodiment, the housing-locking mechanisms 350 and the cover-locking mechanisms 220 comprise extensions that may be joined together by a clip, a clamp, a fastener, etc.

FIG. 4D is a back view 400d of the mount 400 of FIG. 1. Specifically, the slots 440, 450 of the mount 400 are presented clearly in FIG. 4D. In a preferred embodiment, the slots 440, 450 include two different sets of holes. The first set 440 is adapted to engage a C-clamp (not shown) to secure the mount 400, for example, to a pole or a tree. In this sense, one end of the C-clamp would enter through one hole of the slots 440 while the other end of the C-clamp would enter through the other hole of the slots 440. A nut or a pin would then secure the C-clamp to the pole or tree, thereby securing the mount 400 to the pole or tree.

The second set of holes 450 is adapted to engage nails, screws, bolts, etc. In this sense, the mount 400 may be secured to a flat surface by placing the back of the mount to the surface and driving a screw or nail through the second set of holes 450. Additionally, the second set of holes 450 may be used to secure a larger C-clamp (not shown) if the C-clamp is too big to fit into the first set of holes 440. Alternatively, these slots 440, 450 may be threaded with wires, cables, or rope to secure the mount to the tree or pole. In other words, the slots 440, 450 may be used as a securing point for a rope or string to tie the mount 400 to the tree or pole. While the slots 440, 450 provide alternatives to mounting the mount 400, it is also possible to secure the mount 400 to the tree or pole by using an adhesive, thereby removing the need for the slots 440, 450.

FIGS. 5A through 5C are exploded views of the C-shaped recess 310 and the bar 210 of FIGS. 2B and 3B. As shown in FIG. 5A, the C-shaped recess 310 has an opening 315 at one end of the C-shaped recess 310. The opening 315 is a missing portion in an annular-shaped ring, thereby providing a gap of a predefined distance 510. The bar 210 has a cross-section defined by a circle with two flattened portions 215a, 215b. The two flattened portions 215a, 215b are defined by two approximately parallel chords of approximately equal length. If, as shown in FIG. 5A, the two flattened portions 215a, 215b are separated by a distance approximately equal to the predefined distance 510, then the bar 210 may transversely insert into the C-shaped recess 310 when the two flattened portions 215a, 215b are aligned to the opening 315 of the C-shaped recess 310. Additionally, as shown in FIG. 5B, once the bar 210 has been inserted into the C-shaped recess 310, the bar 210 may be removed by aligning the two flattened portions 215 to the opening 315. As shown in FIG. 5C, if the two flattened portions 215a, 215b are not aligned to the opening 315, then the diameter of the cross-section is larger than the opening 315 of the C-shaped recess 310. Thus, when the two flattened portions 215a, 215b are not aligned to the opening 315, the bar 210 is secured within the C-shaped recess 310 and may not transversely disengage the C-shaped recess 310.

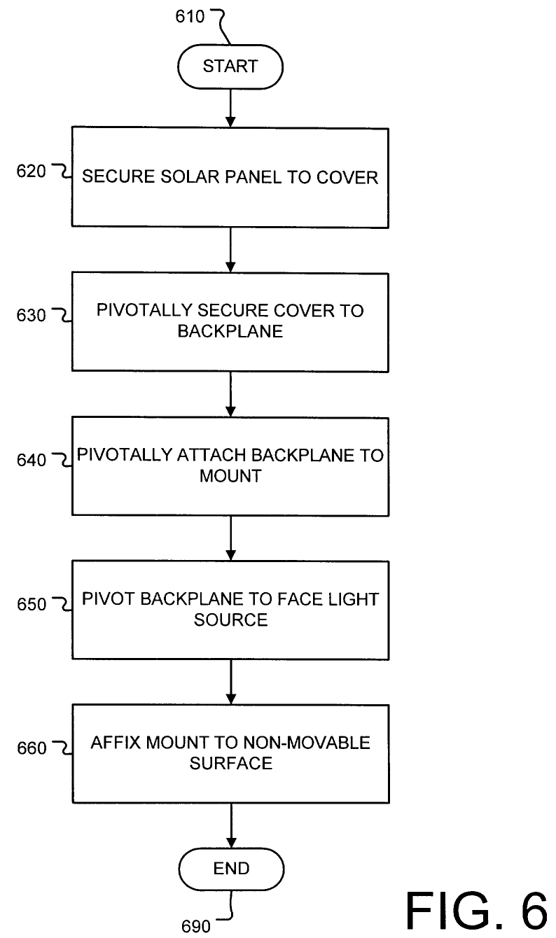

While specific embodiments of solar panel units 100 are shown in FIGS. 1 through 5C, another embodiment may be seen as a method for housing solar panels. One embodiment of the method is shown in FIG. 6.

FIG. 6 is a flowchart showing one embodiment of the method. As shown in FIG. 6, the method may be seen as having the step of securing (620) a solar panel to a cover 200. In a preferred embodiment, the cover 200 has a bar 210 extending from one side of the cover 200 that is substantially parallel to the side of the cover 200. Once the solar panel is secured to the cover 200, a housing 300 is pivotally secured (630) to the cover 200. In a preferred embodiment, the housing 300 has a C-shaped recess 310 with an opening 315. The opening 315 is configured to receive the bar 210 when the bar 210 is transversely inserted into the opening 315.

The housing 300 may further be pivotally attached (640) to a mount 400 and pivoted (650) on the mount 400 to face a light source, thereby providing for maximum exposure of the solar panels to the light source. Once this is done, the mount 400 may be affixed (660) to a non-movable object using a C-clamp, nails, screws, adhesive, or any other securing mechanism.

While the preferred embodiment of the method shows steps associated with the specific embodiments of the system as shown in FIGS. 1 through 5C, it will be clear to one of ordinary skill in the art that the method steps may be performed in other solar panel housing systems that are wholly independent of the specific embodiments of FIGS. 1 through 5C. Thus, the intent is not to limit the method to the specifically described system, but, rather, to cover implementation of the method in other housing systems. Also, process descriptions or blocks in flow charts may be executed out of order from that shown or discussed, including substantially concurrently or in reverse order, depending on the functionality involved, as would be understood by those reasonably skilled in the art of the present invention. Additionally, several steps in the flowcharts may be omitted without detrimental effect to the scope of the invention.

although an exemplary embodiment of the present invention has been shown and described, it will be apparent to those of ordinary skill in the art that a number of changes, modifications, or alterations to the invention as described may be made, none of which depart from the spirit of the present invention. For example, while only three bars 210 and C-shaped recesses 310 are shown in the embodiments of FIGS. 1 through 5C, it will be clear to one of ordinary skill in the art the art that a fewer or greater number of bars 210 and C-shaped recesses 310 may be used depending on the desired level of structural integrity. Additionally, while only four locking mechanisms 220, 350 are shown in the illustrations, it will be clear to one or ordinary skill in the art that fewer or greater number of locking mechanisms may be used depending on the desired level of security. Also, while the cavity 330 is shown as generally cylindrical in shape, it will be clear to one of ordinary skill in the art that the cavity 330 may take any shape depending on the desired internal devices of the solar panel unit 100. Further more, while only a finite set of slots 440, 450 are shown in the mount 400, the number of slots 440, 450 may be increased or decreased as a matter of design choice. Moreover, while friction points 370, 420 are shown in FIGS. 3B and 4B, these friction points may be removed if the rotationally invariant securing mechanism is sufficient to prevent pivoting between the cover 200 and the housing 300. All such changes, modifications, and alterations should therefore be seen as within the scope of the present invention.

What is claimed is:

1. In a communication system having a repeater with circuitry powered by a solar panel, the repeater being interposed between two endpoints, a solar panel unit comprising:
(A) a housing comprising;
(A1) a first connector extending from a first side of the housing, the first connector having a C-shaped recess, the C-shaped recess having an opening;
(A2) a cavity being defined by the housing, the cavity being configured to receive a chargeable cell;
(A3) an orifice configured to receive a wire, the wire being configured to electrically couple the chargeable cell with the repeater, the repeater being located external to the housing;
(A4) a mounting protrusion located external to the housing, the mounting protrusion having an aperture; and
(A5) a first locking mechanism extending from a second side of the housing;
(B) a cover comprising:
(B1) a second connector extending from a first side of the cover, the second connector having a bar, the bar being substantially parallel to the first side of the cover, the bar being configured to engage the C-shaped recess of the first connector, the bar having a cross-section defined by a generally circular outer circumference having two opposing flattened portions, the two opposing flattened portions being separated by a distance approximately equal to the opening on the C-shaped recess, the bar further configured to insert transversely into the opening of the C-shaped recess with minimal resistance when the cover is at a release angle from the housing;
(B2) a concavity located internal to the cover, the concavity configured to receive the solar panel;
(B3) a bracket configured to secure the solar panel to the cover; and
(B4) a second locking mechanism extending from a second side of the cover, the second locking mechanism configured to engage the first locking mechanism on the housing;
(C) a mount configured to pivotally engage the mounting protrusion of the housing, the mount comprising a slot configured to receive a C-clamp, the C-clamp configured to securely attach the mount to a surface; and
(D) a circuit board located within the solar panel unit, the circuit board configured to receive electricity from the solar panel and relay the electricity to the repeater.

2. In a communication system having at least one repeater with circuitry powered by a solar panel, the at least one repeater being interposed between two endpoints, a solar panel unit comprising:
(A) a housing;
(B) a cover; and
(C) a mechanical connector configured to pivotally connect the housing to the cover, the mechanical connector comprising:
(C1) a C-shaped recess having an opening; and
(C2) a bar configured to engage the C-shaped recess of the connector, the bar having a cross-section defined by a generally circular outer circumference having two opposing flattened portions, the two opposing flattened portions being separated by a distance approximately equal to the opening on the C-shaped recess, the bar further configured to insert transversely into the opening of the C-shaped recess with minimal resistance when the cover is at a release angle from the housing.

3. The system of claim 2, further comprising:
a first locking mechanism extending from the housing; and
a second locking mechanism extending from the cover, the second locking mechanism configured to engage the first locking mechanism on the housing.

4. A solar panel unit comprising:
a cover configured to receive a solar panel
a housing; and
a mechanical connector configured to pivotally connect the cover to the housing, the mechanical connector further configured to support pivotal movement of the cover with reference to the housing for movement between a closed position and a range of open positions, the mechanical connector further configured to permit the cover to engage and disengage the housing when the cover is pivoted at a release angle with reference to the housing.

5. The system of claim 4, wherein the first connector comprises a C-shaped recess having an opening.

6. The system of claim 5, wherein the second connector comprises a bar configured to engage the C-shaped recess of the connector.

7. The system of claim 6, wherein the bar has a cross-section defined by a generally circular outer circumference having two opposing flattened portions, the two opposing flattened portions being separated by a distance approximately equal to the opening on the C-shaped recess.

8. The system of claim 7, wherein the bar is further configured to insert transversely into the opening of the C-shaped recess with minimal resistance when the cover and the housing are at a release angle.

9. A solar panel unit comprising:
a housing; and
a cover configured to pivotally connect to the housing, the cover further configured to disengage the housing when the cover is at a release angle from the housing.

10. The system of claim 9, wherein the housing comprises a C-shaped connector having an opening, the opening configured to receive a bar inserted transversely into the opening when the cover is at the release angle with respect to the housing.

11. The system of claim 9, wherein the housing comprises a cavity configured to receive a chargeable cell, the cavity shaped to substantially conform to the shape of the chargeable cell.

12. The system of claim 9, wherein the housing comprises a cavity configured to receive a repeater, the cavity shaped to substantially conform to the shape of the repeater.

13. The system of claim 9, further comprising a mount having a back, the mount further having supports adapted to engage the housing, the supports extending substantially perpendicularly from the back, the mount further having braces extending from one support to the other support, the back configured to securely affix to a non-movable object.

14. The system of claim 13, wherein the housing comprises a mounting protrusion configured to pivotally engage the supports of the mount.

15. The system of claim 14, wherein the mounting protrusion and the supports of the mount comprise friction points, and wherein the friction points are configured to prevent pivotal movement between the mount and the mounting protrusion.

16. The system of claim 9, further comprising a locking mechanism configured to secure the cover to the housing.

17. The system of claim 9, wherein the cover comprises a bar extending from one side of the cover, the bar being substantially parallel to the one side of the cover, the bar being configured to engage an opening in a C-shaped recess, the bar being further configured to transversely insert into the opening of the C-shaped recess.

18. The system of claim 17, wherein the bar has a cross-section defined by a generally circular outer circumference having two opposing flattened portions, the two opposing flattened portions being separated by a distance approximately equal to the opening on the C-shaped recess.

19. The system of claim 9, wherein the cover comprises a concavity configured to receive a solar panel.

20. The system of claim 9, wherein the cover comprises a groove configured to receive a gasket, the gasket adapted to provide a seal between the cover to the housing when the cover and the housing are securely engaged.

21. The system of claim 9, wherein at least one of the cove and the housing is made from a polyvinyl-chloride (PVC) material.

22. The system of claim 9, wherein the PVC material is selected from a group consisting of:
Lexan 503R; and
Lexan 143.

23. The system of claim 9, further comprising a circuit board configured to receive electricity from the solar panel, the circuit board located internal to the solar panel unit.

24. A method for housing a solar panel comprising:
securing a solar panel to a cover, the cover having a bar extending from one side of the cover, the bar being substantially parallel to the one side of the cover; and
pivotally securing the cover to a housing, the housing having a C-shaped recess, the C-shaped recess having an opening, the opening configured to receive the bar, the bar being transversely inserted into the opening.

25. The method of claim 24, further comprising:
pivotally attaching the housing to a mount.

26. The method of claim 25, further comprising:
pivoting the housing on the mount to face a light source.

27. The method of claim 25, further comprising:
affixing the mount to a non-movable object.

28. A solar panel unit comprising:
means for securing a solar panel to a cover; and
means for pivotally securing the cover to a housing.

29. The system of claim 28, further comprising:
means for pivotally attaching the housing to a mount.

30. The system of claim 29, further comprising:
means for pivoting the housing on the mount to face a light source.

31. The system of claim 29, further comprising:
means for affixing the mount to a non-movable object.
